(19) United States
(12) Patent Application Publication
(10) Pub. No.: US 2017/0110642 A1
(43) Pub. Date: Apr. 20, 2017

(54) FOLDED MULTI-LAYERED 2-D VAN DER WAALS MATERIALS AS EFFICIENT THERMOELECTRIC CONVERTERS, AND METHODS THEREOF

(71) Applicant: University of Massachusetts, Boston, MA (US)

(72) Inventors: Zlatan Aksamija, Hadley, MA (US); Robert Blick, Madison, WI (US)

(21) Appl. No.: 15/293,949

(22) Filed: Oct. 14, 2016

Related U.S. Application Data
(60) Provisional application No. 62/241,682, filed on Oct. 14, 2015.

(51) Int. Cl. H01L 35/14; H01L 35/34; H01L 35/32

(52) U.S. Cl. CPC H01L 35/14; H01L 35/32; H01L 35/34

(57) ABSTRACT

The invention provides thermoelectric devices based on folded, multi-layered nanomembranes prepared from 2-dimensional van der Waals materials, and compositions and methods of preparation and use thereof.

### PRIORITY CLAIMS AND RELATED APPLICATIONS

This application claims the benefit of U.S. Provisional Application No. 62/241,682, filed Oct. 14, 2015, the entire content of which is incorporated herein by reference in its entirety.

### STATEMENT REGARDING FEDERALLY FUNDED RESEARCH OR DEVELOPMENT

This invention was made with Government support under Grant No. FA9550-08-1-0337 awarded by Air Force Office of Scientific Research. The Government has certain rights in the invention.

### TECHNICAL FIELDS OF THE INVENTION

The invention generally relates to thermoelectric materials and devices. More particularly, the invention relates to thermoelectric devices based on folded, multi-layered nanomembranes prepared from 2-dimensional van der Waals materials, compositions thereof, and methods for their preparation and use.

### BACKGROUND OF THE INVENTION

Thermoelectric materials and devices have been used to generate electricity and for temperature control and measurement. The thermoelectric effect, on which such devices are based, is a phenomenon where either an electric potential creates a temperature difference or a temperature difference creates an electric potential. In essence, a thermoelectric device creates an electric potential gradient (voltage) when a temperature gradient is present or creates a temperature difference when a electric potential gradient (voltage) is applied to the device.

Good thermoelectric materials are characterized by a high electrical conductivity and low thermal conductivity. There is an extremely high demand for novel and improved thermoelectric materials and devices that provide enhanced conversion efficiency, are easy to fabricate and are suitable for novel applications that existing devices are unable to fulfill.

### SUMMARY OF THE INVENTION

The invention is based on an unconventional approach to thermoelectric system design, materials use, and device fabrication. The invention allows the use of a broad range of van der Waals (vdW) 2-dimensional (2D) materials (e.g., graphene, hexagonal boron nitride, and transition metal dichalcogenides) to achieve dramatically enhanced thermoelectric properties by manipulating the materials so as to substantially de-couple thermal and electrical conductivities.

The novel thermoelectric devices of the invention exhibit significantly improved and tunable conversion efficiency, are easy to fabricate, and are suitable for novel applications that existing devices are unable to satisfy.

In one aspect, the invention generally relates to a device for conversion between thermal and electrical energy. The thermoelectric device includes: a thermoelectric source contact and a thermoelectric drain contact; and a material thermoelectrically connected at a first site to the source contact and at a second site to the drain contact, wherein the material comprises a plurality of folded 2D nanomembranes (e.g., single atomic layers) that are characterized by strong in-plane covalent bonding within a nanomembrane and weak vdW bonding across nanomembranes.

In another aspect, the invention generally relates to a thermoelectric converter having one or more of the devices disclosed herein. In certain embodiments, the thermoelectric converter includes from about two to about 1,000 of modular thermoelectric devices, which can be arranged in any suitable configuration, including being placed in serial and parallel spatial relationships to one another.

In yet another aspect, the invention generally relates to a temperature control unit or an air-conditioning unit having one or more of the thermoelectric devices disclosed herein.

In yet another aspect, the invention generally relates to an electricity generator unit having one or more of the thermoelectric devices disclosed herein.

In yet another aspect, the invention generally relates to a temperature measurement or monitoring device having one or more of the thermoelectric devices disclosed herein.

In yet another aspect, the invention generally relates to a method for manufacturing a device for conversion between thermal and electrical energy. The method includes: providing a plurality of 2D nanomembranes characterized by strong in-plane covalent bonding and weak cross-plane bonding (i.e., weak vdW interactions across nanomembranes); folding the plurality of 2D nanomembranes to form an ordered 3D nanostructure; and forming a thermoelectric connection with a source contact at a first site and a thermoelectric connection with a drain contact at a second site of the ordered 3D nanostructure.

### BRIEF DESCRIPTION OF THE DRAWINGS

FIG. 1. Sketch of the device: principal configuration of layered folded nanomembrane (red) with source and drain contacts.

FIG. 2. Two connected folded 2D vdW nanomembranes, one having an electron gas and the other a hole-gas, are joined to form a 2D nanomembrane-based thermoelectric device.

FIG. 3. Exemplary image of fabricated folded graphene structures implementing the folded nanomembrane thermocouple based on the 2D vdW material graphene.

FIG. 4. Images of the side view (left) and close-up (right) of the folding process.

### DETAILED DESCRIPTION OF THE INVENTION

The invention provides a novel thermoelectric system and device that exhibits significantly improved conversion efficiency over conventional thermoelectric modules. These unique devices are easy to fabricate and are suitable for novel applications that existing devices are unable to fulfill. The devices of the invention are also flexible and can be attached to non-planar surfaces.

More particularly, the invention employs a broad range of 2D materials, e.g., graphene, hexagonal boron nitride, and transition metal dichalcogenides, in the fabrication of thermoelectric devices. The 2D vdW material is manipulated into a uniquely folded, multi-layered, and optionally patterned nanomembrances that are configured to retain excellent electric flow (electric conductivity) while substantially restrict heat flow (heat conductivity). The disclosed thermoelectric device displays a much-enhanced efficiency over conventional thermoelectric devices due to a distinctive manipulation of the 2D vdW material to refashion the relationship between electric and thermal conductivities.

2D vdW materials share the unique property of having single atomic layers with strong in-plane covalent bonding while having weak across-plane bonding via the weak van der Waals force. This unique mechanical anisotropy allows individual single atomic layers to be separated and individually manipulated. The present invention takes advantage of the ultimate thinness of such materials to bend or otherwise re-shape the material to tune or modify its properties to become more suitable for thermoelectric applications.

To improve conversion efficiency, for example, the 2D vdW monolayer materials can be folded into a compact, stacked configuration, which makes the electrical path shorter while obstructing the thermal path. Such a folded, stacked configuration significantly improves the efficiency of the conversion process between thermal and electrical energy and makes the thermoelectric elements superior to unfolded, flat monolayers.

The figure of merit typically used is to assess a thermoelectric device is ZT=(σS²/κ)T, wherein 6 is the electrical conductivity and κ is the thermal conductivity with S being Seebeck-coefficient. The larger the value of ZT, the better the thermoelectric device. As the expression shows, the efficiency relies on the microscopic interplay of the electrical and thermal conductivities. In the case of a very good electrical conductor such as a metal that also has a very good thermal conductivity, increasing 6 leads to an increase in κ and leaves ZT at a low value.

The present invention takes advantage of the fact that the thermal and electrical conductivities in 2D vdW materials (e.g., grapheme) are superior to any other materials. In particular, the thermal conductivity of graphene in plane is of the order of 5,000-W/(mK), the highest ever reported value for any material, exceeding that of diamond. The conduction process is mainly limited by phonon scattering. In addition, the electrical conductivity is very large with electron mobility at room temperature, larger than 15,000-cm²/(Vs) and typically reaching values as high as 200,000-cm²/(Vs). Consequently, electrical conductance can be tuned over a wide range by controlling the density of electrical charges within the graphene sheets. This combination of large thermal and electrical conductance renders a flat layer of graphene inadequate for thermo-electrical device applications. However, if two graphene layers are attached next to each other, the interlayer thermal conductivity is extremely low with a value of below 8-W/(mK) due to the extremely weak van der Waals-type interactions between adjacent layers. This observation also applies to all other 2D materials having the weak van der Waals bonding across atomic monolayers.

In contrast, the electrical conductivity between the individual atomic layers remains very high, due to strong hopping electron transport across the very small spacing between adjacent layers, which in graphene is only 0.335 nm, while other 2D vdW materials have similarly small interlayer spacing below 1 nm. Thus, folding a long and wide ribbon of a 2D vdW material such as graphene multiple times strongly de-couples thermal and electrical conductivity.

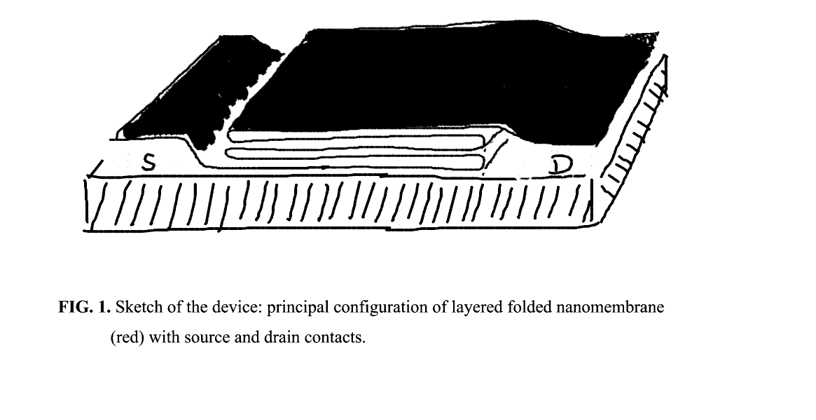

As schematically illustrated in FIG. 1: a single layer of 2D vdW material is deposited on a substrate connecting it to a metallic source contact. Subsequently, the nanomembrane is folded back multiple (e.g., from about 2 to about 4, from about 2 to about 6, from 2 to about 10, about 10 or more) times onto the first layer while making a final contact to a drain electrode. This configuration ensures that the electronic and phononic pathways are sufficiently decoupled.

Without wishing to be bound by the theory, the reasons are believed to be as follows: (a) While electron transport occurs in plane of the nanomembrane, it also occurs vertically to the layers, hence, ‘short-circuiting’ the electron path and turning the stacked nanomembranes from a zigzagged path into a straight path. On the other hand, phonon transport vertically through the stacked layer structure is strongly suppressed. (b) The phonon and electron mean free paths are largely different, leading to extremely strong phonon scattering at the bent edges of the graphene layer. Thus, phonon transport is strongly suppressed.

Once the thermal transport by lattice vibrations (phonons) is suppressed by the folding methodology disclosed herein, the remaining electronic contribution to thermal conductivity is related to electrical conductivity by the Wiedeman-Franz law as L=κ/(σT), where L is the Lorentz constant, given by L=2.44e-8 WΩ/K². In total, based on the suppression of thermal transport and the strong experimentally demonstrated Seebeck-coefficients of 2D vdW class of materials, the thermoelectric figure of merit can be dramatically improved over that of the planar monolayer.

In the example of graphene, having a Seebeck coefficient of S˜120-uV/K, the room temperature ZT-value in this layered device is estimated to be of the order of ZT=S²/L=0.6. At higher temperatures, the ZT-value will continue to increase due to increasing Seebeck-coefficient, reaching a value of 1 at around 600K.

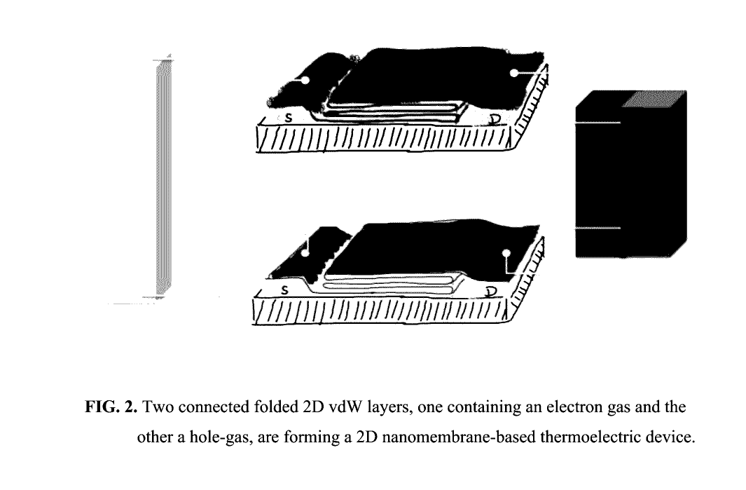

FIG. 2 schematically illustrates a thermoelectric device according to an embodiment of the invention. The thermoelectric device includes a circuit using electrons (red) and holes (blue). Two connected folded 2D vdW layers, one having an electron gas and the other a hole-gas, are joined to form a 2D nanomembrane-based thermoelectric device. The left-hand-side electrode (yellow) is the voltage source, while the right-hand-side electrode indicated the cooling/heating spot.

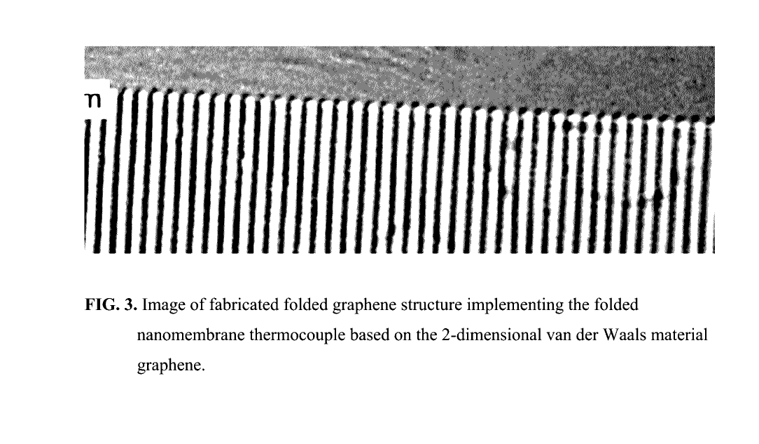

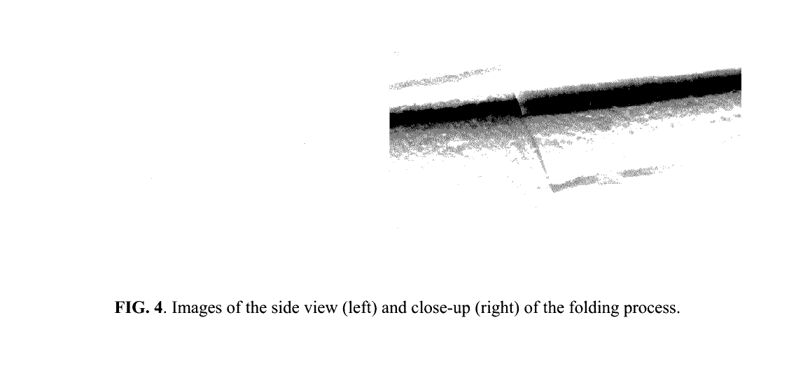

The present invention also includes a thermoelectric system having a multitude of these elements, for example, placed in series and parallel configurations for increased performance (reaching a desired voltage and current rating, for example), as in the exemplary embodiment shown in FIG. 3 and FIG. 4.

In one aspect, the invention generally relates to a device for conversion between thermal and electrical energy. The thermoelectric device includes: a thermoelectric source contact and a thermoelectric drain contact; and a material thermoelectrically connected at a first site to the source contact and at a second site to the drain contact, wherein the material comprises a plurality of folded 2-dimensional nanomembranes characterized by strong in-plane covalent bonding and weak bonding across the nanomembranes.

In certain preferred embodiments, the 2-dimensional nanomembranes are single-atomic nanomembranes. In certain preferred embodiments, the plurality of folded 2-dimensional nanomembranes are stacked sequentially into an ordered 3-D nanostructure.

Any suitable vdW 2D materials may be used the material. In certain embodiments, the vdW 2D material is selected from graphene, hexagonal boron nitride (hBN), phosphorene (mono- or few-layer phosphorus P) or derivatives thereof, including hydrogenated and oxygenated variants. In certain embodiments, the vdW 2D material is selected from silicene, germanene, stananene (mono- or few-layer tin Sn), or derivatives thereof. In certain embodiments, the vdW 2D material is selected from transition metal dichalcogenides, i.e., MX₂, wherein M is a transition metal atom (e.g., Mo, W, Mn) and X is a chalcogen atom (e.g., S, Se, Te).

In certain preferred embodiments, the material is selected from graphene, MoS₂, WSe₂, and phosphorene.

In certain preferred embodiments, the plurality of folded 2D nanomembranes are configured to substantially restrict heat flow between the 2D nanomembrances while substantially retain electric flow therein.

The thermoelectric device disclosed herein exhibits improved conversion efficiencies. In the case of thermal to electric energy conversion efficiency, the device of the invention can have a room temperature ZT-value from about 0.6 to about 1 (e.g., about 0.6, 0.7, 0.8, 0.9, 1.0).

In certain preferred embodiments, the device has an electric to thermal energy conversion efficiency from about 10% to about 15% (e.g., from about 10% to about 13%, from about 10% to about 12%, from about 12% to about 15%) at room temperature.

In certain preferred embodiments, the device has a thermal to electric energy conversion efficiency from about 15% to about 25% (e.g., from about 15% to about 20%, from about 15% to about 18%, from about 18% to about 25%, from about 20% to about 25%) at elevated temperatures above room temperature (e.g., 30° C., 35° C., 40° C., 45° C., 50° C., 55° C., 60° C.).

In another aspect, the invention generally relates to a thermoelectric converter having one or more of the devices disclosed herein. In certain embodiments, the thermoelectric converter includes from about 2 to 1,000 (e.g., from about 2 to about 500, from about 2 to about 100, from about 2 to about 50, from about 2 to about 20, from about 2 to about 10, from about 2 to about 5, from about 5 to about 1,000, from about 10 to about 1,000, from about 20 to about 1,000, from about 50 to about 1,000, from about 100 to about 1,000, from about 20 to about 1,000) of modular thermoelectric devices, which can be arranged in any suitable configuration, including being placed in serial and/or parallel spatial relationships to one another.

In yet another aspect, the invention generally relates to a temperature control or air conditioning unit having one or more of the devices disclosed herein.

In yet another aspect, the invention generally relates to an electricity generator unit having one or more of the devices disclosed herein.

In yet another aspect, the invention generally relates to a temperature measurement or monitoring device having one or more of the devices disclosed herein.

In yet another aspect, the invention generally relates to a method for manufacturing a device for conversion between thermal and electrical energy. The method includes: providing a plurality of 2D nanomembranes characterized by strong in-plane covalent bonding and weak bonding across the nanomembranes; folding the plurality of 2D nanomembranes to form an ordered 3D nanostructure; and forming a thermoelectric connection with a source contact at a first site and a thermoelectric connection with a drain contact at a second site of the ordered 3D nanostructure.

In certain preferred embodiments of the method, the 2D nanomembranes are single-atomic nanomembranes. In certain preferred embodiments of the method, the plurality of folded 2D nanomembranes are stacked sequentially into an ordered 3-D nanostructure.

In certain embodiments of the method, the 2D nanomembranes are made from a material selected from graphene, hexagonal boron nitride (hBN) and phosphorene, and derivatives thereof.

In certain embodiments of the method, the 2D nanomembranes are made from a material selected from silicence and germanance, and derivatives thereof.

In certain embodiments of the method, the 2D nanomembranes are made from a transition metal dichalcogenide, MX₂, wherein M is a transition metal atom and X is a chalcogen atom. In certain preferred embodiments of the method, M is selected from Mo, W and Mn and X is selected from S, Se and Te.

In certain preferred embodiments of the method, the 2D nanomembranes are made from a material is selected from graphene, MoS₂, WSe₂ and phosphorene.

In certain embodiments of the method, the plurality of folded 2-dimensional nanomembranes are configured to substantially restrict heat flow between the 2D nanomembrances while substantially retain electric flow therein.

The 2-dimensional nanomembranes may have any suitable sizes, for example, ranging from about 1 mm² to about 1,000 cm² (e.g., from about 1 mm² to about 500 cm², from about 1 mm² to about 100 cm², from about 1 mm² to about 50 cm², from about 10 mm² to about 1,000 cm², from about 100 mm² to about 1,000 cm², from about 10 cm² to about 1,000 cm², from about 100 cm² to about 1,000 cm²).

The thermo-element disclosed herein can be suitable for a variety of applications for energy conversion (e.g., generating electricity or heat), temperature control (e.g., refrigeration, air conditioning), or temperature monitoring or measurement. An exemplary use of the disclosed devices may be found in waste-heat scavenging in a wide range of heat-generating processes, including car exhausts, industrial plants, and combined solar-thermal generators.

Applicant's disclosure is described herein in preferred embodiments with reference to the Figures, in which like numbers represent the same or similar elements. Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

The described features, structures, or characteristics of Applicant's disclosure may be combined in any suitable manner in one or more embodiments. In the following description, numerous specific details are recited to provide a thorough understanding of embodiments of the invention. One skilled in the relevant art will recognize, however, that Applicant's composition and/or method may be practiced without one or more of the specific details, or with other methods, components, materials, and so forth. In other instances, well-known structures, materials, or operations are not shown or described in detail to avoid obscuring aspects of the disclosure.

In this specification and the appended claims, the singular forms “a,” “an,” and “the” include plural reference, unless the context clearly dictates otherwise.

Unless defined otherwise, all technical and scientific terms used herein have the same meaning as commonly understood by one of ordinary skill in the art. Although any methods and materials similar or equivalent to those described herein can also be used in the practice or testing of the present disclosure, the preferred methods and materials are now described. Methods recited herein may be carried out in any order that is logically possible, in addition to a particular order disclosed.

### Incorporation by Reference

References and citations to other documents, such as patents, patent applications, patent publications, journals, books, papers, web contents, have been made in this disclosure. All such documents are hereby incorporated herein by reference in their entirety for all purposes. Any material, or portion thereof, that is said to be incorporated by reference herein, but which conflicts with existing definitions, statements, or other disclosure material explicitly set forth herein is only incorporated to the extent that no conflict arises between that incorporated material and the present disclosure material. In the event of a conflict, the conflict is to be resolved in favor of the present disclosure as the preferred disclosure.

### Equivalents

The representative examples are intended to help illustrate the invention, and are not intended to, nor should they be construed to, limit the scope of the invention. Indeed, various modifications of the invention and many further embodiments thereof, in addition to those shown and described herein, will become apparent to those skilled in the art from the full contents of this document, including the examples and the references to the scientific and patent literature included herein. The examples contain important additional information, exemplification and guidance that can be adapted to the practice of this invention in its various embodiments and equivalents thereof.

1. A device for conversion between thermal and electrical energy, comprising:
a thermoelectric source contact and a thermoelectric drain contact; and
a material thermoelectrically connected at a first site to the source contact and at a second site to the drain contact, wherein the material comprises a plurality of folded 2-dimensional nanomembranes characterized by strong in-plane covalent bonding and weak bonding across the nanomembranes.

2. The device of claim 1, wherein the 2-dimensional nanomembranes are single-atomic nanomembranes.

3. The device of claim 2, wherein the plurality of folded 2-dimensional nanomembranes are stacked or connected into an ordered 3-dimensional nanostructure.

4. The device of claim 1, wherein the material is selected from graphene, silicene, hexagonal boron nitride (hBN), MoS₂, WSe₂, phosphorene and stananene, and derivatives thereof.

5. The device of claim 4, wherein the material is hydrogenated and oxygenated.

6. The device of claim 1, wherein the material is selected from silicence, germanance, and derivatives thereof.

7. The device of claim 1, wherein the material is a transition metal dichalcogenide, MX₂, wherein M is a transition metal atom and X is a chalcogen atom.

8. The device of claim 7, the transition metal is selected from Mo, W and Mn;
and the chalcogen is selected from S, Se and Te.

9. The device of claim 4, wherein the material is graphene.

10. The device of claim 1, wherein the plurality of folded 2-dimensional nanomembranes are configured to substantially restrict heat flow between the 2-dimensional nanomembrances while substantially retain electric flow therein.

11. The device of claim 1, having a thermal to electric energy conversion efficiency from about 10 to about 15 percent.

12. The device of claim 1, having an electric to thermal energy conversion efficiency from about 15 to about 25 percent at an elevated temperature.

13. A thermoelectric converter comprising one or more of the device of claim 1.

14. (canceled)

15. A temperature control or air conditioning unit comprising one or more of the device of claim 1.

16. An electricity generator unit comprising one or more of the device of claim 1.

17. A temperature measurement device comprising one or more of the device of claim 1.

18. A method for manufacturing a device for conversion between thermal and electrical energy, comprising:
providing a plurality of 2-dimensional nanomembranes characterized by strong in-plane covalent bonding and weak bonding across the nanomembranes;
folding the plurality of 2-dimensional nanomembranes to form an ordered 3-D nanostructure; and
forming a thermoelectric connection with a source contact at a first site and a thermoelectric connection with a drain contact at a second site of the ordered 3-D nanostructure.

19. The method of claim 18, wherein the 2-dimensional nanomembranes are single-atomic nanomembranes.

20. The method of claim 18, wherein the plurality of folded 2-dimensional nanomembranes are stacked sequentially into an ordered 3-dimensional nanostructure.

21. The method of claim 18, wherein the 2-dimensional nanomembranes are made from a material selected from graphene, silicene, hexagonal boron nitride (hBN), MoS₂, WSe₂, phosphorene and stananene, and derivative thereof.

22-29. (canceled)
